(19) United States
(12) Patent Application Publication
(10) Pub. No.: US 2003/0211672 A1
(43) Pub. Date: Nov. 13, 2003

(54) Method of improving quality of interface between gate and gate oxide

(76) Inventor: June-Min Yao, Hsinchu (TW)

Correspondence Address: J.C. Patents, Inc., Suite 250, 4 Venture, Irvine, CA, 92618, US

(21) Appl. No.: 10/144,134

(22) Filed: May 10, 2002

(51) Int. Cl. H01L 21/336

(52) U.S. Cl. 438/197

(57) ABSTRACT

A method of improving quality of an interface between a gate and a gate oxide layer is disclosed. The method begins by providing a substrate with a gate oxide layer formed thereon. A nitrogen containing plasma treatment is then performed on the gate oxide layer, so that a top surface of the gate oxide layer is reacted to form a silicon oxy-nitride layer. A polysilicon layer is formed on the silicon oxy-nitride layer and subsequently patterned to form a polysilicon gate.

### BACKGROUND OF THE INVENTION

1. Field of Invention

The present invention relates a semiconductor process. More particularly, the present invention relates a method of improving quality of an interface between a gate and a gate oxide layer.

2. Description of Related Art

A metal oxide semiconductor (MOS) device has a basic structure comprising a semiconductor substrate, a gate oxide layer that forms on the substrate, a gate that forms on the gate oxide layer, and a source/drain (S/D) region that forms in a portion of the substrate located on both sides of the gate. The MOS device has a switch which is controlled by the gate, while thickness and quality of the gate oxide layer is one key factor that determines such electrical conductivity of the MOS device.

In the conventional semiconductor process, the gate is formed by depositing a polysilicon layer with a reactive gas such as silane (SiH₄). As silane would react with silicon dioxide during deposition of the polysilicon layer on the gate oxide layer, a part of the gate oxide layer is consumed. This results in a non-uniform thickness of the gate oxide layer, which in turns lowers reliability of the device. For example, in the current process for fabricating a gate oxide layer with a thickness lower than 100 angstroms. If a part of the gate oxide layer were reduced by a thickness of about 25-30 angstroms during the deposition of the polysilicon layer, such reduction would significantly affect the electrical conductivity of the device. Also, it is possible Boron (B) ion that is doped into the polysilicon layer can penetrate gate oxide layer and diffuse into the substrate. Consequently, it becomes harder to control the electrical conductivity of the device.

### SUMMARY OF THE INVENTION

Accordingly, the present invention provides a method of improving quality of an interface between a gate and a gate oxide layer. The method includes providing a substrate with a gate oxide layer formed thereon. A nitrogen containing plasma treatment, such a nitrogen gas plasma treatment is performed on the gate oxide layer, so that a top surface of the gate oxide layer is reacted to form a silicon oxy-nitride layer. A polysilicon layer is formed on the silicon oxy-nitride layer. The polysilicon layer is then doped with Boron ion and patterned to form a polysilicon gate.

To achieve these and other advantages and in accordance with the purpose of the invention, as embodied and broadly described herein, the invention provides a method of improving quality of an interface between a gate and a gate oxide layer, which method includes reacting the top surface of the gate oxide layer with the nitrogen containing plasma to form a silicon oxy-nitride layer. A polysilicon layer is then deposited on the silicon oxy-nitride layer. Since silane (SiH₄) used in the deposition of the polysilicon layer does not react easily with the silicon oxy-nitride layer, this prevents formation of the gate oxide layer with an uneven thickness, while further obtaining a device having a uniform conductive type. In addition, the silicon oxynitride layer is a denser structure compared to the gate oxide layer. So, the Boron ion that is doped into the polysilicon layer does not easily penetrate the silicon oxy-nitride layer and diffuse into the underlying substrate.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIGS. 1A-1C are schematic diagrams illustrating the method of improving quality of an interface between a gate and a gate oxide layer according to the one preferred embodiment.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

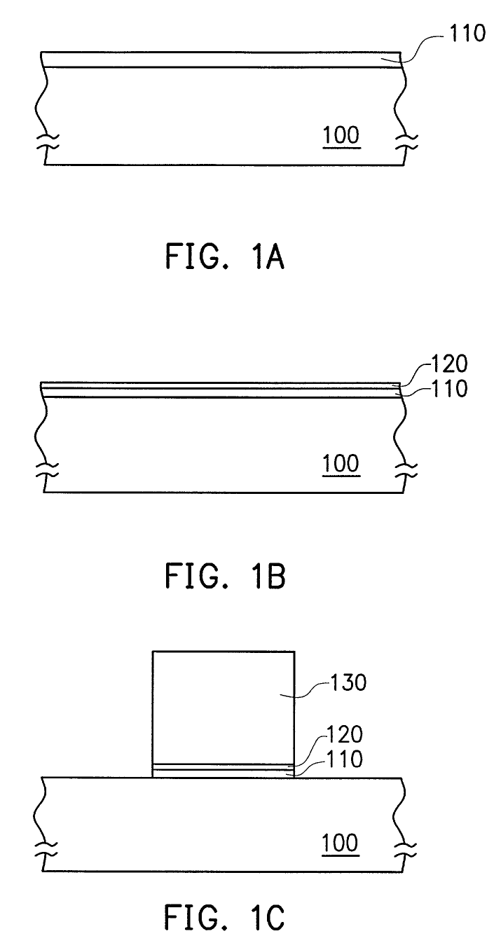

Referring to FIG. 1A, a substrate 100 is provided with a gate oxide layer 110 already formed thereon. The gate oxide layer 110 may also be a tunnel oxide layer that is used in a non-volatile memory (NVM).

Referring to FIG. 1B, the gate oxide layer 110 is treated with a nitrogen-containing plasma, such as a nitrogen gas plasma. Such plasma treatment results a reaction between highly active nitrogen radicals from the gas plasma and a top surface of the gate oxide layer 110 to form a silicon oxy-nitride layer 120.

Referring to FIG. 1C, a polysilicon layer (not shown) is deposited on the silicon oxy-nitride layer 120, with silane (SiH₄) serving as a reactive gas. The polysilicon layer may be doped with Boron (B) ions. As the silicon oxy-nitride layer does not react easily with silane, the gate oxide layer 110 underneath the silicon oxy-nitride layer 120 can be protected. As a result, thickness of the gate oxide layer 110 and the silicon oxy-nitride layer 120 would not be uneven. Next, the polysilicon layer is patterned to form a polysilicon gate 130, with the gate oxide layer 110 and the silicon oxy-nitride layer 120 underneath the polysilicon gate 130 having a uniform thickness.

As described above, the top surface of the gate oxide layer 110 reacts with the nitrogen containing plasma to form the silicon oxy-nitride layer 120. A polysilicon layer is then deposited on the silicon oxy-nitride layer 120. Since silane (SiH₄) used in the deposition of the polysilicon layer does not react easily with the silicon oxy-nitride layer 120, this prevents formation of the gate oxide layer 110 with an uneven thickness, while obtaining a device having a uniform conductive type.

In addition, the silicon oxy-nitride layer 120 is a denser structure compared to the gate oxide layer 110. So, the Boron ion that is doped into the polysilicon gate 130 does not easily penetrate the silicon oxy-nitride layer 120 and diffuse into the underlying substrate 100. Although the present embodiment has used the method of improving the interface between the gate and the gate oxide layer in a process of fabricating a MOS transistor, the invention was not limited to only improving the interface between polysilicon gate and the gate oxide layer. The invention can be equally applicable to improving any interface between oxide layer and polysilicon layer that is formed using a reactive gas that can react with the oxide layer.

In summary, the invention is capable of improving quality of the interface between the gate and the gate oxide layer. By forming a silicon oxy-nitride layer on the gate oxide layer through a nitrogen-containing plasma treatment, an uniform thickness of the gate oxide layer and the silicon oxy-nitride layer be maintained, since no gate oxide layer would be damaged by reacting with the silane used in the polysilicon deposition step.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of improving quality of an interface between a gate and a gate oxide layer, the method comprising steps of:
providing a substrate with the gate oxide layer formed thereon;
performing a nitrogen-containing plasma on the gate oxide layer, so that a top surface of the gate oxide layer is reacted to form a silicon oxy-nitride layer;
depositing a polysilicon layer on the silicon oxy-nitride layer; and
patterning the polysilicon layer to form a polysilicon gate.

2. The method of claim 1, wherein the nitrogen-containing plasma includes a nitrogen gas plasma.

3. The method of claim 1, wherein the gate oxide layer includes a tunnel oxide layer.

4. The method of claim 1, wherein the step of depositing a polysilicon layer includes a chemical vapor deposition using SiH₄ as a reactive gas.

5. The method of claim 1, further includes doping the polysilicon gate with Boron ions.

6. A method of improving quality of an interface between a gate and a gate oxide layer, the method comprising steps of:
providing a substrate with the gate oxide layer formed thereon;
performing a nitrogen gas plasma on the gate oxide layer, so that a top surface of the gate oxide layer is reacted to form a silicon oxy-nitride layer;
depositing a polysilicon layer on the silicon oxy-nitride layer; and
patterning the polysilicon layer to form a polysilicon gate.

7. The method of claim 6, wherein the gate oxide layer includes a tunnel oxide layer.

8. The method of claim 6, wherein the step of depositing a polysilicon layer includes a chemical vapor deposition using SiH₄ as a reactive gas.

9. The method of claim 6, further includes doping the polysilicon gate with Boron ions.
